(19) United States
(12) Patent Application Publication
(10) Pub. No.: US 2006/0103034 A1
(43) Pub. Date: May 18, 2006

(54) Overlay mark for a non-critical layer of critical dimensions

(76) Inventors: Kuo-Kuei Fu, Shanghai (CN); Chou Meng Hsing, Shanghai (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 10/986,908

(22) Filed: Nov. 15, 2004

(51) Int. Cl. H01L 23/544

(52) U.S. Cl. 257/797; 257/E23.179

(57) ABSTRACT

An overlay mark for monitoring the critical dimension of a non-critical layer, comprising four first bars which are bar-shaped and separated from each other. The four first bars enclose to form a rectangle, and each first bar is correspondingly parallel to each side of the rectangle. The four second bars, wherein each second bar is bar-shaped and separated from each other, and the four second bars are positioned in the rectangle, and each second bar is correspondingly parallel to each side of the rectangle and comprise a plurality of third bars parallel with each other.

### BACKGROUND OF THE INVENTION

1. Field of the Invention

The present invention relates to an overlay mark, in particular, to an overlay mark for monitoring the critical dimensions of a non-critical layer.

2. Description of the Prior Art

As the dimension of the semiconductor becomes smaller, and with higher levels of integration, fabrication processes become more complicated and more difficult. Thus, the direction of semiconductor manufacturers has turned to monitoring and controlling, by employing real-time measuring devices, to respond or solve problems in real-time so as to lower damages caused by fabrication process errors.

Generally, other than controlling the critical dimensions of a wafer, the factor governing the success or failure of a wafer photolithography process is alignment accuracy. Thus, alignment accuracy measurement, or overlay error measurement, is an important task in the semiconductor fabrication process. An overlay mark is applied as a tool for measuring overlay error and is used to determine the alignment accuracy of the pattern of a photoresist layer after a photolithography process with that of a previous layer over the chip. In the process of monitoring alignment accuracy, a monitoring beam scans across the overlay. After scanning, signals representing the mean value of the position of the overlay are measured, compared, and the differences, i.e., overlay error, are calculated. If the overlay error is larger than the acceptable deviation value, this means that the alignment between the pattern of the photoresist layer and that of the chip has not reached the accuracy requirements, and a second photolithography process has to be repeated until the overlay error is smaller than the acceptable deviation value.

Although alignment accuracy can be monitored, the time and the cost used in fabrication process are increased.

### SUMMARY OF THE INVENTION

The present invention provides an overlay mark for monitoring the critical dimension of the non-critical layer, in which the monitoring time is reduced.

The present invention also provides an overlay mark for monitoring the critical dimension of the non-critical layer, in which the overlay mark comprises a plurality of bars for monitoring alignment accuracy readily.

To achieve the aforementioned objects, a preferred embodiment of the present invention provides an overlay mark for monitoring the critical dimension of the non-critical layer, comprising four first bars which are bar-shaped and separated from each other. The four first bars enclose to form a rectangle, and each first bar is correspondingly parallel to each side of the rectangle. Four second bars, wherein each second bar is bar-shaped and separated from each other, and the four second bars are positioned in a rectangle, and each second bar is correspondingly parallel to each side of the rectangle and comprise a plurality of third bars paralleled with each other.

These and other objectives of the present invention will become obvious to those of ordinary skill in the art after reading the following detailed description of the preferred embodiment.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a top view of an overlay mark in accordance with a preferred embodiment of the present invention; and

FIG. 2 is a top view of a second bar in accordance with a preferred embodiment of the present invention.

### DETAILED DESCRIPTION OF THE PREFERRED EMBODIMENTS

The present invention provides an overlay mark for monitoring the critical dimension of the non-critical layer, comprising four first bars which are all bar-shaped and separated from each other. The first bars enclose to form a rectangle. Each first bar is correspondingly parallel with each side of the rectangle. Four second bars, which are all bar-shaped and separated from each other, are positioned in the rectangle. Each second bar is correspondingly adjacent to each first bar and is composed of a plurality of third bars which are parallel with each other. Each third bar is vertically and correspondingly positioned.

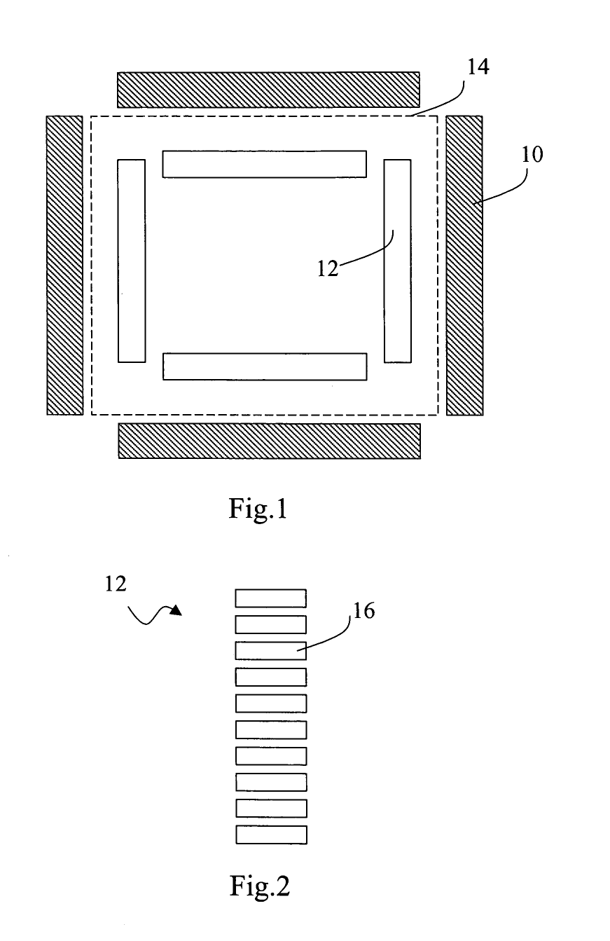

FIG. 1 is a top view of an overlay mark in accordance with a preferred embodiment of the present invention. As shown in FIG. 1, the overlay mark comprises four first bars 10 and four second bars 12, which are all bar-shaped. Four first bars enclose to form a rectangle 14. Each first bar is separated from each other and is correspondingly parallel with each side of the rectangle 14. The first bars 10 represent the location of the fore-layer.

In addition, each of the four second bars 12 in the rectangle 14 is separated from each other and is correspondingly parallel with each side of the rectangle 14. That is, each second bar 12 is parallel and adjacent (but not close to) to the corresponding first bar 10. In this embodiment of the present invention, since four second bars are positioned in the rectangle 14, the length of the second bar 12 is shorter than the length of the first bar 10.

FIG. 2 is a top view of a second bar in accordance with a preferred embodiment of the present invention. In this embodiment of the present invention, each second bar is composed of a plurality of third bars 16, which are all bar-shaped and separated form each other. The third bars 16 are vertical correspondingly to the side of the rectangle 14, and vertical correspondingly to the first bars 10. It should be noted that the distances between the third bars 16 are not limited, and are designed depending on the requirement or designed by simulation in order to obtain the ideal values. One of the advantages of the present invention is that the third bars that are parallel and separated from each other are used for monitoring the critical dimension of the non-critical layer. The principle of monitoring of the present invention is by employing line-end shortening of the second bars 12 having the third bars 16 formed during defocus and employing the characteristic of non-influence by the defocus at the etched first bars. The third bars 16 cause a center shift as a result of the defocus during the measuring of alignment accuracy, and thus, by reverse calculation of the amount of center shift, a relative defocus is obtained. Based on this principle, monitoring the critical dimension of the non-critical layer can be obtained readily.

The embodiment above is only intended to illustrate the present invention; it does not, however, to limit the present invention to the specific embodiment. Accordingly, various modifications and changes may be made without departing from the spirit and scope of the present invention as described in the following claims.

What is claimed is:

1. An overlay mark for monitoring critical dimension of a non-critical layer, comprising
four first bars, wherein each first bars is bar-shaped and separated from each other and the four first bars enclose to form a rectangle, and each first bar is correspondingly parallel to each side of the rectangle; and
four second bars, wherein each second bar is bar-shaped and separated from each other, and the four second bars are positioned in the rectangle, and each second bar is correspondingly parallel to each side of the rectangle and comprise a plurality of third bars parallel with each other.

2. The overlay mark for monitoring critical dimension of a non-critical layer of claim 1,
wherein each third bar is vertical to the corresponding side of the rectangle.

3. The overlay mark for monitoring critical dimension of a non-critical layer of claim 1,
wherein each third bar is separated from each other.

4. The overlay mark for monitoring critical dimension of a non-critical layer of claim 1,
wherein the length of each second bar is shorter than the length of an adjacent first bar.

5. An overlay mark for monitoring critical dimension of a non-critical layer, comprising
four first bars, wherein each first bar is bar-shaped and separated from each other and the four first bars enclose to form a rectangle, and each first bar is correspondingly parallel to each side of the rectangle; and
four second bars, wherein each second bar is bar-shaped and separated from each other, and the four second bars are positioned in the rectangle, and each second bar is correspondingly parallel to each side of the rectangle and comprise a plurality of third bars parallel with each other, and wherein each third bar is vertical to the corresponding side of the rectangle.

6. The overlay mark for monitoring critical dimension of a non-critical layer of claim 5,
wherein each third bar is separated from each other.

7. The overlay mark for monitoring critical dimension of a non-critical layer of claim 5,
wherein the length of each second bar is shorter than the length of an adjacent first bar.
